(19) United States
(12) Patent Application Publication
(10) Pub. No.: US 2022/0093363 A1
(43) Pub. Date: Mar. 24, 2022

(54) Alternating Current (AC) Dual Magnetron Sputtering

(71) Applicant: Advanced Energy Industries, Inc., Fort Collins, CO (US)

(72) Inventors: Paul Romanus, Nashua, NH (US); Matthew James Lacy, Fort Collins, CO (US); Douglas R. Pelleymounter, Northfield, MN (US)

(21) Appl. No.: 17/086,347

(22) Filed: Oct. 31, 2020

Related U.S. Application Data
(60) Provisional application No. 63/082,157, filed on Sep. 23, 2020.

(51) Int. Cl. H01J 37/32; H01J 37/34; H03H 7/42; C23C 14/35

(52) U.S. Cl. CPC H01J 37/32183; H01J 37/321; C23C 14/35; H03H 7/42; H01J 37/34

(57) ABSTRACT

Power systems, sputtering systems, and sputtering methods are disclosed. A sputtering system comprises at least one electrode pair comprising a first electrode and a second electrode, and each electrode of the dual electrode pair is configured to support target material. The sputtering system also includes a generator configured to provide an alternating voltage waveform and at least one balun comprising a balanced side coupled to the first electrode and the second electrode and an unbalanced side coupled to the generator. The sputtering system also includes means for inductively coupling power, applied from the generator, from the unbalanced side to the balanced side.

### CLAIM OF PRIORITY UNDER 35 U.S.C. § 119

The present application for patent claims priority to Provisional Application No. 63/082,157 entitled “AC Dual Magnetron Sputtering” filed Sep. 23, 1920 and assigned to the assignee hereof and hereby expressly incorporated by reference herein.

### FIELD

The present invention relates generally to power conversion, and more specifically to power systems producing time-varying power.

### BACKGROUND

Sputtering historically includes generating a magnetic field in a vacuum chamber and causing a plasma beam in the chamber to strike a sacrificial target, thereby causing the target to sputter (eject) material, which is then deposited as a thin film layer on a substrate, sometimes after reacting with a process gas. Sputtering sources may employ magnetrons that utilize strong electric and magnetic fields to confine charged plasma particles close to the surface of the target. In the context of RF sputtering, a single power supply in connection with a single magnetron is traditionally used, and in these systems power during one half of a periodic voltage cycle is used for sputtering.

The industry continues to evolve in various attempts to maximize sputtering efficiency and/or increase the types of target materials that may be used in the system.

### SUMMARY

According to one aspect, a power system comprises a balun including a balanced side and an unbalanced side, a match network coupled to the unbalanced side of the balun, and two output nodes coupled to the balanced side of the balun. The power system also includes a generator configured to provide an alternating voltage waveform to the two output nodes via the match network and the balun.

Another aspect may be characterized as a sputtering system comprising at least one electrode pair comprising a first electrode and a second electrode, wherein each electrode of the electrode pair is configured to support target material to be sputtered. The sputtering system also comprises a generator configured to provide an alternating voltage waveform and at least one balun, wherein the balun comprises a balanced side with a first output coupled to the first electrode, a second output coupled to the second electrode, an unbalanced side coupled to the generator, and means for inductively coupling power applied from the generator from the unbalanced side to the balanced side.

Yet another aspect may be characterized as a method for sputtering that comprises producing an alternating voltage waveform with a generator, applying the voltage waveform to an unbalanced side of a balun, and inductively coupling the unbalanced side of the balun to a balanced side of the balun to produce a balanced alternating waveform, which is applied across two electrodes to sputter material from the two electrodes.

### BRIEF DESCRIPTION OF THE DRAWINGS

FIG. 1 is a block diagram depicting aspects of an exemplary system;

FIG. 2 is a diagram depicting aspects of a balun that may be used in the system of FIG. 1;

FIG. 3 is a diagram depicting aspects of another balun that may be used in the system of FIG. 1;

FIG. 4 is a schematic representation of the balun depicted in FIG. 3;

FIG. 5 is a diagram depicting yet another balun that may be used in connection with embodiments disclosed herein; and

FIG. 6 is a block diagram depicting components of a controller that may be utilized in connection with embodiments disclosed herein.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

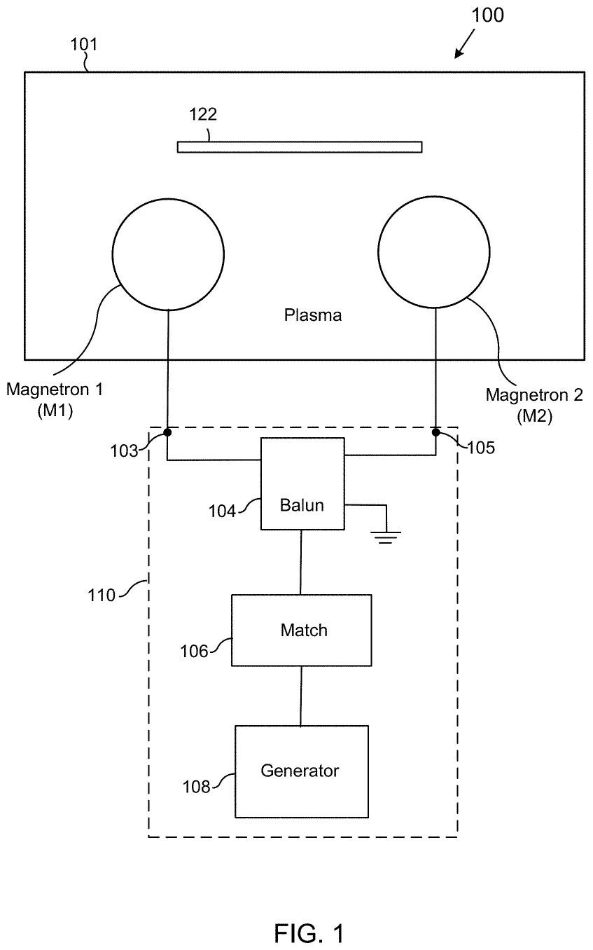

Referring to FIG. 1, an exemplary sputtering system 100 is shown. An aspect of the system 100 is that (with the same number of generators and match networks as prior art magnetron sputtering approaches) embodiments described herein enable the production of desirable films with more favorable deposition rates as compared to the prior sputtering approaches. For example, aspects described further herein enable one generator-match system to be connected to multiple electrodes (e.g., magnetrons).

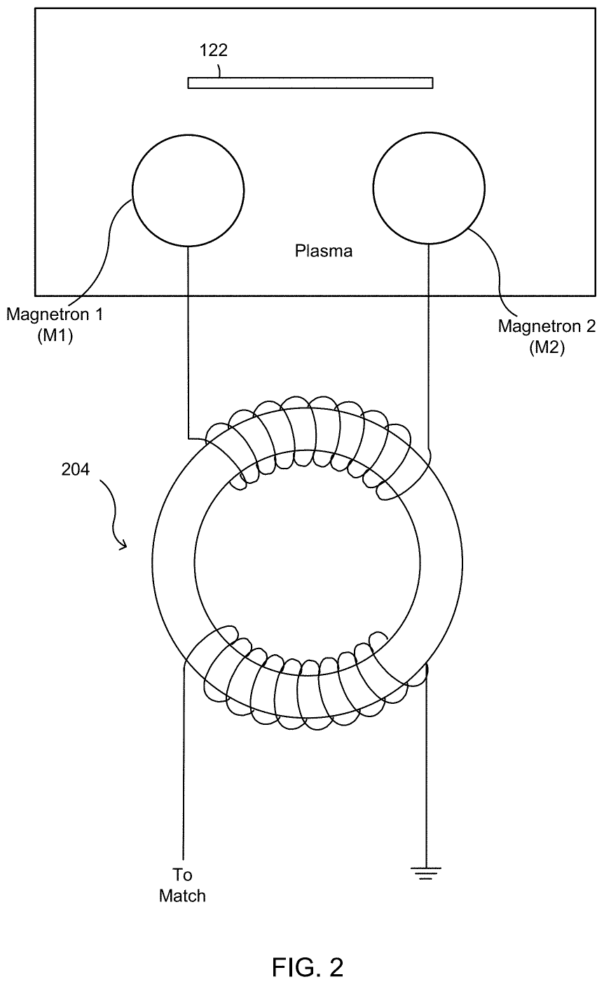

As shown in FIG. 1, the sputtering system 100 includes a plasma chamber 101 enclosing at least one electrode pair: a first magnetron M1 and a second magnetron M2. The sputtering system 100 includes a substrate 122 upon which the system 100 deposits a thin film material in a sputtering process. Although the sputtering system 100 includes two electrodes, in general N electrodes may be used where N is greater than or equal to two. As discussed further herein with reference to FIGS. 2, 3, and 5 in many implementations N is an even number greater than or equal to two. As shown, the first magnetron M1 is coupled to a first output node 103 of a balun 104 and a second magnetron M2 is coupled to second output node 105 of the balun 104, and the balun 104 is coupled to a match 106, and the match 106 is coupled to a generator 108. In this system, the unbalanced side of the balun 104 is coupled to ground and the match 106, and the balanced side of the balun 104 is coupled to the first magnetron M1 and the second magnetron M2.

It should be recognized that the at least electrode pair need not be realized by magnetrons, but in many sputtering applications magnetrons are utilized due to beneficial aspects that are well known to those of ordinary skill in the art. It should also be recognized that the balun 104, match 106, and generator 108 may be separately sold as a power system 110 apart from the plasma chamber 101 and that the plasma chamber 101 is depicted as an example of an application where the power system may be utilized.

In operation, the generator 108 applies power via a transmission line (e.g., coaxial cable) to the match 106, and the match 106 couples power to the balun 104 via another electrical connection. And in turn, the balun 104 inductively couples the power to both the first magnetron M1 and the second magnetron M2. Although the voltage applied by the generator 108 may vary depending on many factors including the electrode (e.g., magnetron) construction, the power setpoint, etc., the peak to peak voltage is generally hundreds of volts and may be around 400 volts in one exemplary implementation.

Although not shown in FIG. 1, gases may be provided to the plasma chamber 101, and a plasma is sustained within the chamber 101 in response to the application of a periodic voltage waveform across the magnetrons M1, M2, which support target material. In some embodiments, there may be reactant gases and ion peening gases fed into the plasma chamber 101. The reactant gases may include, for example, nitrogen, oxygen, and the ion peening gas may be argon. Exemplary target materials include, without limitation, indium tin oxide, indium gallium zinc oxide, and silicon dioxide.

The generator may operate at any of a variety of frequencies including frequencies higher than 400 kHz to provide an alternating voltage waveform. Beneficially, sputtering-power is applied to the first magnetron M1 during one half of a cycle of the periodic waveform, and then sputtering power is applied to the second magnetron M2 during the other half of the cycle. As a consequence, sputtering may occur substantially constantly over an entire cycle of the periodic waveform. This is in contrast to single magnetron systems in the prior art that only sputter during half of a cycle as discussed above.

Although the generator 108 may operate at a variety of frequencies, in many implementations, the generator 108 operates at frequencies of at least 400 kHz. For example, without limitation, the generator 108 may operate at 400 kHz, 450 kHz, 13.56 MHz, 27 MHz, and 40 MHz, but these frequencies are only exemplary. It is contemplated that the generator 108 may apply arbitrary-shaped waveforms at lower frequencies, but at higher frequencies, it is more difficult to provide waveforms other than sinusoidal waveforms. In many implementations of the power system 110, the generator 108 operates to regulate applied power based upon a power setpoint received from an operator of the system 100. The power for example, may be at least 1.5 kW. As specific examples, the power may be 1.5 kW, 5 kW, or 15 kW, but other power levels are certainly contemplated. The generator 108 may be implemented by a PARAMOUNT power supply sold by Advanced Energy Industries, Inc. of Fort Collins, Colo., U.S.A., but this is not required, and other types of power supplies may be used.

The match 106 (also referred to as a match network 106) generally operates to provide impedance matching between the generator 108 and a load presented to the generator 108. For example, the match 106 may operate so that the generator 108 “sees” an impedance that is substantially the same as a source impedance of the generator 108. In some implementations, the match 106 operates to provide impedance matching by sensing reflected power and altering its impedance to provide a low (e.g., substantially minimized) level of reflected power. In some embodiments, the generator 108 may be capable of augmenting capabilities of the match 106 by carrying out frequency tuning (by adjusting a frequency of the generator 108 to assist with impedance matching). The match 106 may be implemented by a NAVIGATOR II match network sold by Advanced Energy Industries, Inc. of Fort Collins, Colo., U.S.A., but this is not required, and other types of match networks may be used.

Referring next to FIG. 2, shown is an exemplary balun 204 that may be used to realize the balun 104 depicted in FIG. 1. The balun 204 in FIG. 2 is sometimes referred to as a Ruthroff-type voltage balun, which includes a single coil at an unbalanced primary side of the balun 204 and a single secondary coil on a balanced side that is coupled to the two magnetrons, M1, M2. In many implementations, a core of the balun 204 is toroidal in shape, but it is contemplated that other core configurations may be utilized. The material used to realize the core may vary depending upon desired characteristics of the balun 204, but in many implementations, non-magnetic material is utilized for the core.

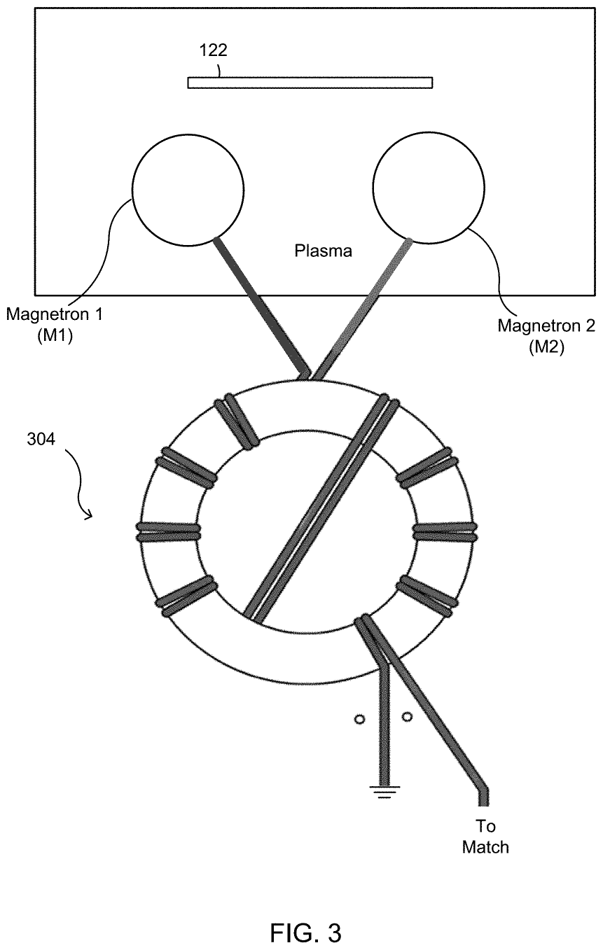

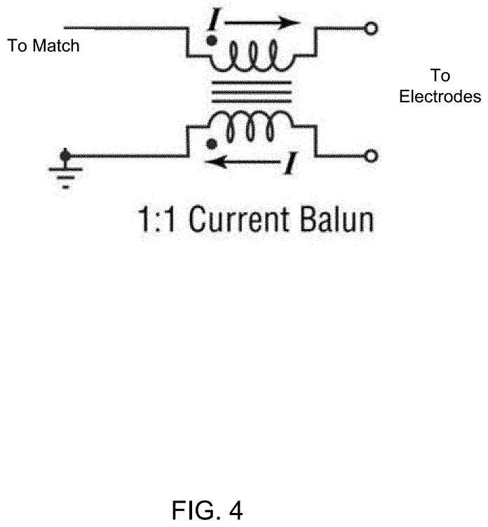

Referring to FIG. 3, shown is another exemplary balun 304 that may be used to realize the balun 104 depicted in FIG. 1. The balun 304 in FIG. 3 is sometimes referred to as a Guenella-type 1:1 current balun, and as shown, an unbalanced primary side of the balun 304 is positioned to couple to the match 106 and the secondary coil on a balanced side is coupled to the two magnetrons, M1, M2. The choking reactance of the Guenalla RF transformer isolates the input and output of the balun and balances the output. It also chokes off any currents on the outside of the shield that may be caused by a slightly unbalanced load. The balun 304 also has a wider bandwidth than the Ruthroff voltage balun. In many implementations, a core of the balun 304 is toroidal in shape, but it is contemplated that other core configurations may be utilized. The balun 304 may be sized to be a 10 kW balun, but this is not required and other sizes may be utilized depending upon the application. The material used to realize the core may vary depending upon desired characteristics of the balun 304, but in many implementations, non-magnetic material is utilized for the core. A schematic representation of the 1:1 current balun is shown in FIG. 4.

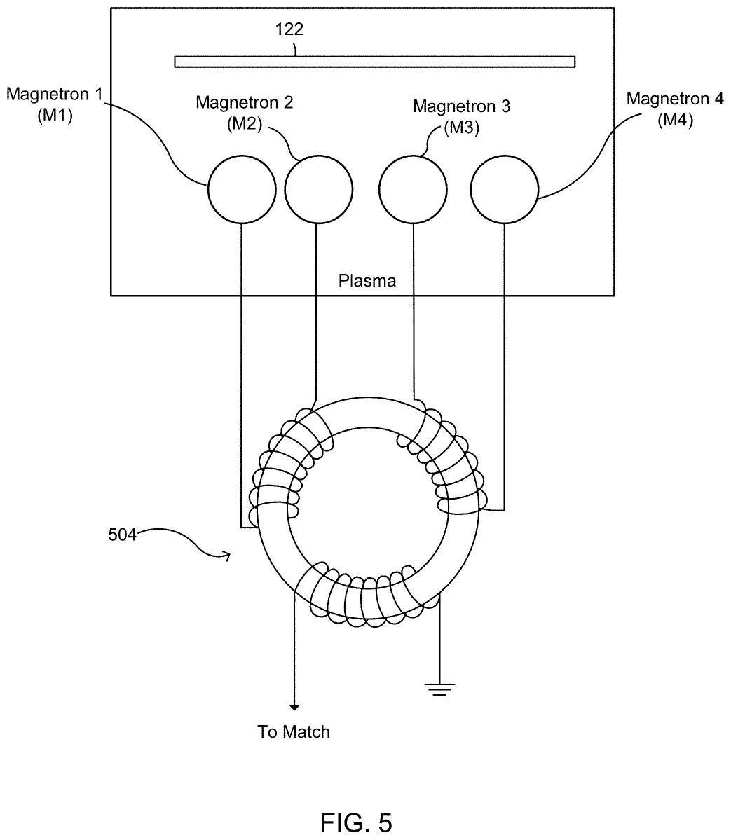

In the implementation depicted in FIG. 5, the balun 504 includes two electrically separate secondary coils. As shown, a first secondary coil is coupled to both the first magnetron M1 and the second magnetron M2; thus, providing balanced power to each of the first and second magnetrons M1, M2. And a second secondary coil is coupled to a third magnetron M3 and a fourth magnetron M4 to provide balanced current to the third and fourth magnetrons M3 and M4. In yet other variations, additional secondary coils may be added to the balun 504, and in connection with each additional secondary coil, two additional magnetrons may be powered. For example, a single generator-match combination may be used with a balun that has three secondary coils that are used to apply power to six magnetrons.

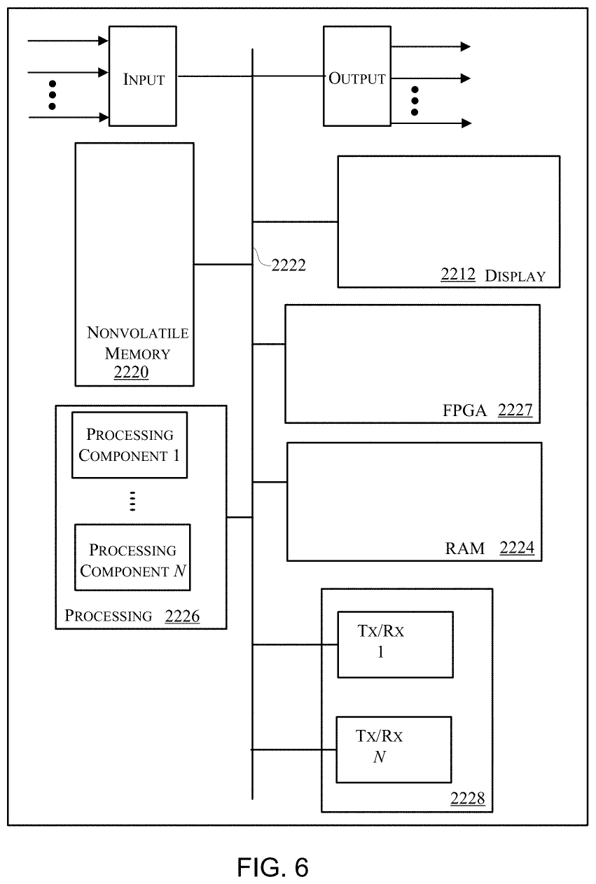

Although not shown, the generator 108 and the match 106 may include controllers that may be realized by hardware, firmware or a combination of software and hardware and/or hardware and firmware. Referring to FIG. 6 example, shown is a block diagram depicting physical components that may be utilized to realize controllers according to an exemplary embodiment. As shown, in this embodiment a display 2212 and nonvolatile memory 2220 are coupled to a bus 2222 that is also coupled to random access memory (“RAM”) 2224, a processing portion (which includes N processing components) 2226, a field programmable gate array (FPGA) 2227, and a transceiver component 2228 that includes N transceivers. Although the components depicted in FIG. 6 represent physical components, FIG. 6 is not intended to be a detailed hardware diagram; thus, many of the components depicted in FIG. 6 may be realized by common constructs or distributed among additional physical components. Moreover, it is contemplated that other existing and yet-to-be developed physical components and architectures may be utilized to implement the functional components described with reference to FIG. 6.

This display 2212 generally operates to provide a user interface for a user, and in several implementations, the display 2212 is realized by a touchscreen display. In general, the nonvolatile memory 2220 is non-transitory memory that functions to store (e.g., persistently store) data and processor executable code (including executable code that is associated with effectuating the methods described herein). In some embodiments for example, the nonvolatile memory 2220 includes bootloader code, operating system code, file system code, and non-transitory processor-executable code to facilitate control of the generator 108 and/or match 106 in connection with methods described herein.

In many implementations, the nonvolatile memory 2220 is realized by flash memory (e.g., NAND or ONENAND memory), but it is contemplated that other memory types may be utilized. Although it may be possible to execute the code from the nonvolatile memory 2220, the executable code in the nonvolatile memory is typically loaded into RAM 2224 and executed by one or more of the N processing components in the processing portion 2226.

The N processing components in connection with RAM 2224 generally operate to execute the instructions stored in nonvolatile memory 2220 to enable the generator 108 and/or the match 106 to achieve one or more objectives. For example, non-transitory processor-executable instructions to effectuate the methods described herein may be persistently stored in nonvolatile memory 2220 and executed by the N processing components in connection with RAM 2224. As one of ordinary skill in the art will appreciate, the processing portion 2226 may include a video processor, digital signal processor (DSP), graphics processing unit (GPU), and other processing components.

In addition, or in the alternative, the FPGA 2227 may be configured to effectuate one or more aspects of the methodologies described herein. For example, non-transitory FPGA-configuration-instructions may be persistently stored in nonvolatile memory 2220 and accessed by the FPGA 2227 (e.g., during boot up) to configure the FPGA 2227 to effectuate the functions of a generator and/or match controller.

The input component may operate to receive signals that are indicative of one or more aspects of the power applied to the electrodes (e.g., magnetrons and/or the anodes). The signals received at the input component may include, for example, voltage, current, and/or power. The output component generally operates to provide one or more analog or digital signals to effectuate an operational aspect of the generator 108 (e.g., a power setting) or match 106 (e.g., match setting).

The depicted transceiver component 2228 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A power system comprising:
a balun including a balanced side and an unbalanced side;
a match network coupled to the unbalanced side of the balun;
two output nodes coupled to the balanced side of the balun; and
a generator configured to provide an alternating voltage waveform to the two output nodes via the match network and the balun.

2. The power system of claim 1, wherein the balun is a current balun configured to balance current.

3. The power system of claim 2, wherein the balun is a 1:1 Guenella-type balun.

4. The power system of claim 1, wherein the balun is a Ruthroff-type voltage Balun.

5. The power system of claim 1, wherein the generator is configured to operate at frequencies of at least 400 kHz.

6. The power system of claim 1, wherein the generator is configured to operate at a power level of at least 1.5 kW.

7. The power system of claim 1, wherein the generator is configured to apply a sinusoidal alternating voltage waveform.

8. A sputtering system comprising:
at least one electrode pair comprising a first electrode and a second electrode, each electrode of the electrode pair is configured to support target material to be sputtered;
a generator configured to provide an alternating voltage waveform;
at least one balun comprising:
a balanced side comprising a first output coupled to the first electrode;
a second output coupled to the second electrode;
an unbalanced side coupled to the generator; and
means for inductively coupling power applied from the generator from the unbalanced side to the balanced side.

9. The sputtering system of claim 8, comprising a match network coupled between the generator and the unbalanced side of the balun to couple the alternating voltage waveform from the generator to the balun.

10. The sputtering system of claim 8, wherein the balun is a current balun configured to balance current.

11. The sputtering system of claim 10, wherein the balun is a 1:1 Guenella-type balun.

12. The sputtering system of claim 8, wherein the balun is a Ruthroff-type voltage Balun.

13. The sputtering system of claim 8, wherein the generator is configured to operate at frequencies of at least 400 kHz.

14. The sputtering system of claim 8, wherein the generator is configured to operate at a power level of at least 1.5 kW.

15. The sputtering system of claim 8, wherein the generator is configured to apply a sinusoidal alternating voltage waveform.

16. A method for sputtering comprising;
producing an alternating voltage waveform with a generator;
applying the voltage waveform to an unbalanced side of a balun;
inductively coupling the unbalanced side of the balun to a balanced side of the balun to produce a balanced alternating waveform; and
applying the balanced alternating waveform across two electrodes to sputter material from the two electrodes.

17. The method of claim 16 comprising:
transforming an impedance presented to the generator with a match network.

18. The method of claim 16 wherein inductively coupling the unbalanced side of the balun to a balanced side of the balun comprises inductively coupling the unbalanced side of the balun to a balanced side with a current balun configured to balance current.

19. The method of claim 18 wherein inductively coupling the unbalanced side of the balun to a balanced side of the balun comprises inductively coupling the unbalanced side of the balun to a balanced side with a 1:1 Guenella-type balun.

20. The method of claim 16 wherein inductively coupling the unbalanced side of the balun to a balanced side of the balun comprises inductively coupling the unbalanced side of the balun to a balanced side with a Ruthroff-type voltage Balun.
